(19) United States
(12) Patent Application Publication
(10) Pub. No.: US 2024/0170269 A1
(43) Pub. Date: May 23, 2024

(54) SYSTEM AND METHODS FOR DEPOSITING MATERIAL ON A SUBSTRATE

(71) Applicant: Applied Materials, Inc., Santa Clara, CA (US)

(72) Inventor: Harish PENMETHSA, Dublin, CA (US)

(21) Appl. No.: 17/990,536

(22) Filed: Nov. 18, 2022

(51) Int. Cl. H01J 37/34; C23C 14/35; H01J 37/32

(52) U.S. Cl. CPC H01J 37/3426; C23C 14/35; H01J 37/32082; H01J 37/3244; H01J 37/32715; H01J 37/3405; H01J 37/3455; H01J 37/347; H01J 2237/2007; H01J 2237/20207; H01J 2237/20214; H01J 2237/332

(57) ABSTRACT

A physical vapor deposition (PVD) chamber deposits thin films on substrates having through-vias (TVs) formed therethrough in an electronic device fabrication process. More particularly, apparatus and methods improve film deposition uniformity when the TVs have a high aspect ratio or are otherwise shaped in a manner that can decrease the deposition of sputtered material. A sacrificial plate is used below the substrate in a manner whereby material is sputtered into the TVs from below in addition to the conventional top-down sputtering.

### BACKGROUND

### Field

Embodiments of the present disclosure generally relate to physical vapor deposition (PVD) film formation on substrates in an electronic device fabrication process, and more particularly, to apparatus and methods for improving film uniformity in features formed on a substrate by utilizing a sacrificial plate of target material at a lower surface of a substrate.

### Description of the Related Art

Electronic device fabrication processes today often involve the use of a physical vapor deposition (PVD), or sputtering, process in a dedicated PVD chamber. The source of the sputtered material may be a planar or rotary sputtering target formed from pure metals, alloys, or ceramic materials. A magnet array, which is typically disposed within an assembly that is often referred to as a magnetron, is used to generate a magnetic field in the vicinity of the target. During processing, a high voltage is applied to the target to generate a plasma and enable the sputtering process. Because the voltage source is negatively biased, the target may also be referred to as the “cathode.” The high voltage generates an electric field inside the PVD chamber that is used to enable sputtering of the target material and generate and emit electrons from the target that are used to generate and sustain a plasma near the underside of the target. The magnet array applies an external magnetic field that traps electrons and confines the plasma close to the target. The trapped electrons can then collide with and ionize the gas atoms disposed within the processing region of the PVD chamber. The collision between the trapped electron(s) and gas atoms will cause the gas atoms to emit electrons that are used to sustain and further increase the plasma density within the processing region of the PVD chamber. The plasma may include argon atoms, positively charged argon ions, free electrons, and ionized and neutral metal atoms sputtered from the target. The argon ions are accelerated towards the target due to the negative bias and collide with a surface of the target causing atoms of the target material to be ejected therefrom. The ejected atoms of target material then travel towards the substrate and chamber shielding to incorporate into the growing thin film thereon.

PVD sputtering and control of film uniformity are especially challenging when processing large-area substrates, such as panels. As used herein, the term “panel” may refer to a large-area substrate that contains a large surface area. For example, a common panel size may be 600 mm by 600 mm. In some packaging applications, common panel materials can include polymer materials, such as Ajinomoto Build-up Film (ABF), Copper Clad Laminate (CCL), panel with polymer on top, glass, or other similar materials.

Uniformity is equally important in a PVD process when the substrate includes features, such as vias that extend all the way through the substrate. Through-vias (TVs) are a critical technology for three-dimensional integrated circuit and chip packaging technologies. These through-substrate interconnects allow electronic devices to be stacked vertically for a broad range of applications and performance improvements such as increased bandwidth, reduced signal delay, improved power management, and smaller form-factors. In a typical PVD operation, the target is located above the surface of the substrate and will generally cause a non-conformal coating to be deposited within the features formed on or within the surface of the substrate. However, the vertical walls of through-vias (TVs) that extend through the substrate are challenging to coat as their surface is typically perpendicular or near perpendicular to the surface of the target. The problem is exacerbated when the via has a high aspect ratio or when the via walls are formed in a manner whereby the bottom of the via has a larger diameter than the upper portion, as in the case of an hourglass shaped via. Vias that extend through a substrate with varying inside diameters are often unavoidable when creating the features within the substrate. The result is poor thickness uniformity and actual coverage of the sputtered material on the walls of the via. FIGS. 1A-C include section views of a number of vias having high aspect ratios and in some instances, include enlarged lower diameters. In each example 216a-c, the non-uniform inner walls of the TVs 500a-c can be appreciated.

Accordingly, there is a need in the art for apparatus and methods for improving film deposition uniformity on the walls of features formed in a substrate.

### SUMMARY

Embodiments described herein generally relate to a physical vapor deposition (PVD) chamber having a pedestal disposed within a processing region of the PVD chamber. The pedestal has an upper surface that is configured to support a sacrificial plate thereon and the sacrificial plate is configured to support a substrate. A biasing source provides a bias to the sacrificial plate. A lid assembly comprises a target, wherein a surface of the target defines a portion of the processing region, and comprises a target material.

More particularly, embodiments described herein provide apparatus and methods for improving film deposition uniformity when depositing a layer within features formed in a substrate, especially those with high aspect ratios or enlarged bottom diameters.

In one embodiment, a PVD chamber includes a pedestal disposed within a processing region of the PVD chamber, the pedestal having an upper surface that is configured to support a sacrificial plate which in turn supports a substrate, a first motor coupled to the pedestal, the first motor configured to rotate the pedestal about a first axis that is perpendicular to at least a portion of the upper surface of the pedestal, and a lid assembly housing a target. A biasing source is provided to the sacrificial plate and a gas inlet is provided to deliver process gas through gas apertures in the sacrificial plate to a space between the sacrificial plate and the TVs formed in the substrate. The gas apertures are fed process gas through a gas manifold internal to the pedestal. In one embodiment, the sacrificial plate is constructed of the same material as a target. A surface of the target defines a portion of the processing region, and comprises a target material. A surface area of the upper surface of the pedestal is greater than a surface area of the surface of the target. The surface of the target is tilted at a first angle in relation to a plane of the upper surface of the pedestal. The target comprises one or more cooling channels configured to receive a coolant there through for cooling the target. The PVD chamber includes a first magnetron disposed over a portion of the target, and in a region of the lid assembly that is maintained at atmospheric pressure, a first actuator configured to translate the first magnetron in a first direction, a second actuator configured to translate the first magnetron in a second direction which is approximately perpendicular to the first direction, wherein the process of translating of the first magnetron, by the second actuator, comprises rotating the first magnetron about a second axis, and a system controller that is configured to cause the first magnetron to translate along at least a portion of a first path by causing the first actuator and second actuator to simultaneously translate the first magnetron.

Embodiments of the disclosure may include a physical vapor deposition (PVD) chamber, including a pedestal disposed within a processing region of the PVD chamber, the pedestal having an upper surface that is configured to support a sacrificial plate which in turn supports a substrate, a first motor coupled to the pedestal and a lid assembly comprising a target. A biasing source is provided to the sacrificial plate and a gas inlet is provided to deliver process gas through gas apertures in the sacrificial plate to a space between the sacrificial plate and the TVs formed in the substrate. The gas apertures are fed process gas through a gas manifold internal to the pedestal. A first magnetron is disposed over a portion of the target and in a region of the lid assembly that is maintained at atmospheric pressure, a first actuator configured to translate the first magnetron in a first direction, wherein translating the first magnetron, by the first actuator, comprises rotating the first magnetron about a second axis, a second actuator configured to translate the first magnetron in a second direction, and a system controller that is configured to cause the first magnetron to translate along at least a portion of a first path by causing the first actuator and second actuator to simultaneously translate the first magnetron. The first motor configured to rotate the pedestal about a first axis that is perpendicular to at least a portion of the upper surface of the pedestal. The lid assembly comprising a target, wherein a surface of the target defines a portion of the processing region, and comprises a target material, a surface area of the upper surface of the pedestal is greater than a surface area of the surface of the target, and the surface of the target is tilted at a first angle in relation to a plane of the upper surface of the pedestal.

Embodiments of the disclosure may include a sacrificial plate for use in a PVD processing chamber, the sacrificial plate including a shape generally conforming to a substrate to be supported on an upper surface of the sacrificial plate, the upper surface including target material for deposition; a plurality of gas apertures extending through the sacrificial plate for providing processing gas from a lower surface to the upper surface of the sacrificial plate; a connection member formed in the sacrificial plate that is configured to receive an electrical bias provided from a bias source; and a plurality of fastening features formed in the sacrificial plate, wherein the fastening features are used to attach the sacrificial plate to an upper surface of a pedestal in a manner whereby the gas apertures are aligned with gas outlets integrally formed in the pedestal.

Embodiments of the disclosure may include a method of utilizing a sacrificial plate in a PVD processing chamber, including providing the sacrificial plate having a shape generally conforming to a substrate to be supported on an upper surface of the sacrificial plate, the upper surface including target material for deposition; providing a plurality of gas apertures extending through the sacrificial plate for providing processing gas from a lower surface to the upper surface of the sacrificial plate; providing a connection member formed in the sacrificial plate that is configured to receive an electrical bias provided from a bias source; providing a plurality of fastening features formed in the sacrificial plate, wherein the fastening features are used to attach the sacrificial plate to an upper surface of a pedestal in a manner whereby the gas apertures are aligned with gas outlets integrally formed in the pedestal; and conducting a processing operation in the chamber, whereby target material from the sacrificial plate is sputtered onto the substrate.

Embodiments of the disclosure may include a substrate support for use in a processing chamber, comprising: a sacrificial plate having an upper surface configured to support a substrate thereon, and the sacrificial plate comprises a target material; a plurality of gas apertures extending through the sacrificial plate for providing processing gas from a lower surface to the upper surface of the sacrificial plate; a connection member formed in the sacrificial plate that is configured to receive an electrical bias provided from a bias source; and a plurality of fastening features formed in the sacrificial plate, wherein the fastening features are used to attach the sacrificial plate to an upper surface of a pedestal in a manner whereby the gas apertures are aligned with gas outlets formed in the pedestal.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A-C are sectional side views of several through-vias (TVs) formed in a substrate and illustrating the varied inside diameters and aspect ratios of the TVs.

FIG. 2 is a schematic top view of an exemplary substrate processing system, according to certain embodiments.

FIG. 3A is a side cross-sectional view of a PVD chamber that may be used in the substrate processing system of FIG. 2, shown with the substrate in a loaded position.

FIG. 3B is a side cross-sectional view of a PVD chamber that may be used in the substrate processing system of FIG. 2, shown with the substrate in a processing position.

FIG. 3C is a top view of a portion of FIG. 3A illustrating an overlay of a target and a substrate, according to certain embodiments.

FIG. 4 is a top view of a substrate having four segmented portions, according to certain embodiments.

FIG. 5 is a top view of a sacrificial plate, according to certain embodiments.

FIG. 6 is a partial section view showing a gas manifold assembly and gas apertures for permitting gas to reach the underside of the substrate according to certain embodiments.

FIG. 7 is a partial section view showing a protective cover over a fastener attaching the sacrificial plate to the pedestal.

FIG. 8 is a pre-processing partial section view taken along a line 8-8 of FIG. 5 and illustrating the TVs formed in the substrate.

FIG. 9 is a section view of the substrate showing TVs after having been processed and coated with sputtered material.

FIG. 10 is a section view of a different embodiment of a PVD chamber with the substrate shown in the loading position.

FIG. 11 is a section view of the chamber of FIG. 10 with the substrate in the processing position.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Embodiments of the disclosure provided herein generally relate to physical vapor deposition (PVD) of thin films on substrates having features, such as through-vias (TVs) formed therethrough by use of an electronic device fabrication process. More particularly, embodiments described herein provide apparatus and methods for improving film deposition uniformity when the TVs have a high aspect ratio or are otherwise shaped in a manner that can decrease the deposition of sputtered material across the surfaces of the via. In the embodiments herein, a sacrificial plate is used below the substrate in a manner whereby material is sputtered into the TVs from below in addition to the conventional top-down sputtering.

### Exemplary Substrate Processing System

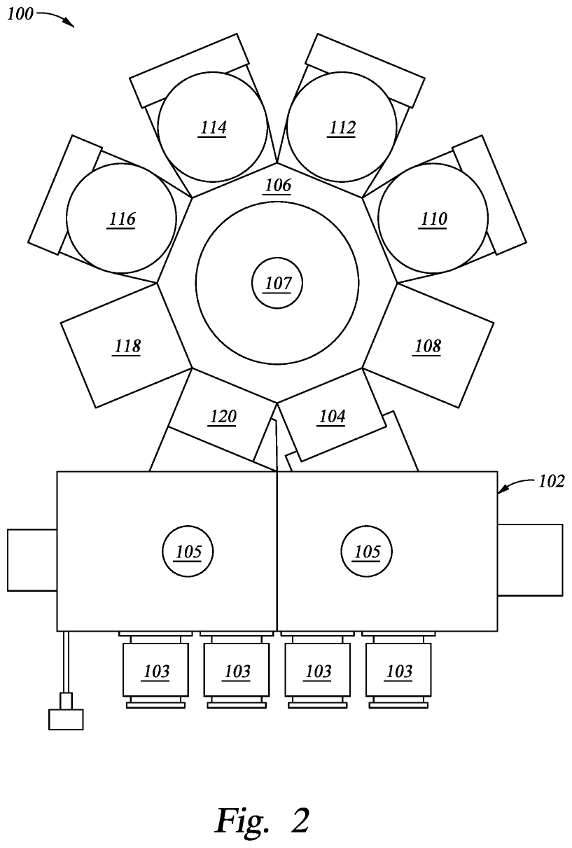

FIG. 2 is a schematic top view of an exemplary substrate processing system 100 (also referred to as a “processing platform”), according to certain embodiments. In certain embodiments, the substrate processing system 100 is particularly configured for processing large-area substrates, such as panels as described above. The substrate processing system 100 generally includes an equipment front-end module (EFEM) 102 for loading substrates into the processing system 100, a first load lock chamber 104 coupled to the EFEM 102, a transfer chamber 106 coupled to the first load lock chamber 104, and a plurality of other chambers coupled to the transfer chamber 106 as described in detail below. The front-end module (EFEM) 102 generally includes one or more robots 105 that are configured to transfer substrates from the FOUPs 103 to at least one of the first load lock chamber 104 or the second load lock chamber 120. Proceeding counterclockwise around the transfer chamber 106 from the first load lock chamber 104, the processing system 100 includes a first dedicated degas chamber 108, a first pre-clean chamber 110, a first deposition chamber 112, a second pre-clean chamber 114, a second deposition chamber 116, a second dedicated degas chamber 118, and a second load lock chamber 120. In certain embodiments, the transfer chamber 106 and each chamber coupled to the transfer chamber 106 are maintained at a vacuum state. As used herein, the term “vacuum” may refer to pressures less than 760 Torr, and will typically be maintained at pressures near 10⁻⁵ Torr (i.e., ˜10⁻³ Pa). However, some high-vacuum systems may operate below near 10⁻⁷ Torr (i.e., ˜10⁻⁵ Pa). In certain embodiments, the vacuum is created using a rough pump and/or a turbomolecular pump coupled to the transfer chamber 106 and to each of the one or more process chambers (e.g., process chambers 108-118). However, other types of vacuum pumps are also contemplated.

In certain embodiments, substrates are loaded into the processing system 100 through a door (also referred to as an “access port”), in the first load lock chamber 104 and unloaded from the processing system 100 through a door in the second load lock chamber 120. In certain embodiments, a stack of substrates is supported in a cassette disposed in the FOUP, and are transferred therefrom by a robot 105 to the first load lock chamber 104. Once vacuum is pulled in the first load lock chamber 104, one substrate at a time is retrieved from the load lock chamber 104 using a robot 107 located in the transfer chamber 106. In certain embodiments, a cassette is disposed within the first load lock chamber 104 and/or the second lock chamber 120 to allow multiple substrates to be stacked and retained therein before being received by the robot 107 in the transfer chamber 106 or robot 105 in the EFEM 102. However, other loading and unloading configurations are also contemplated.

Pre-cleaning of the substrates is important to remove impurities, such as oxides, from the substrate surface, so that films (e.g., metal films) deposited in the deposition chambers are not electrically insulated from the electrically-conductive metal surface area of the substrate by the layer of impurities. By performing pre-cleaning in the first and second pre-clean chambers 110, 114, which share the vacuum environment similar to the first and second deposition chambers 112, 116, the substrates can be transferred from the cleaning chambers to the deposition chambers without being exposed to atmosphere. This prevents formation of impurities on the substrates during the transfer. In addition, vacuum pump-down cycles are reduced since a vacuum is maintained in the substrate processing system 100 during transfer of the cleaned substrates to the deposition chambers. In some embodiments, when a cassette is empty or full in the first load lock chamber 104 or the second load lock chamber 120 the processing system 100 may cause either of the load lock chambers to break vacuum so that one or more substrate can be added or removed therefrom.

In certain embodiments, only one substrate is processed within each pre-clean and deposition chamber at a time. Alternatively, multiple substrates may be processed at one time, such as four to six substrates. In such embodiments, the substrates may be disposed on a rotatable pallet within the respective chambers. In certain embodiments, the first and second pre-clean chambers 110, 114 are inductively coupled plasma (ICP) chambers for etching the substrate surface. However, other types of pre-clean chambers are also contemplated. In certain embodiments, one or both of the pre-clean chambers are replaced with a film deposition chamber that is configured to perform a PVD, chemical vapor deposition (CVD), or atomic layer deposition (ALD) process, such as deposition of silicon nitride.

In a pre-clean chamber that includes an ICP source, a coil at the top of the chamber is energized with an external RF source to create an excitation field in the chamber. A pre-clean gas (e.g., argon, helium) flows through the chamber from an external gas source. The pre-clean gas atoms in the chamber are ionized (charged) by the delivered RF energy. In some embodiments, the substrate is biased by a RF biasing source. The charged atoms are attracted to the substrate resulting in the bombardment and/or etching of the substrate surface. Other gases besides argon may be used depending on the desired etch rate and the materials to be etched.

In certain embodiments, the first and second deposition chambers 112, 116 are PVD chambers. In such embodiments, the PVD chambers may be configured to deposit copper, titanium, aluminum, gold, and/or tantalum. However, other types of deposition processes and materials are also contemplated.

### Exemplary PVD Chamber and Method of Use

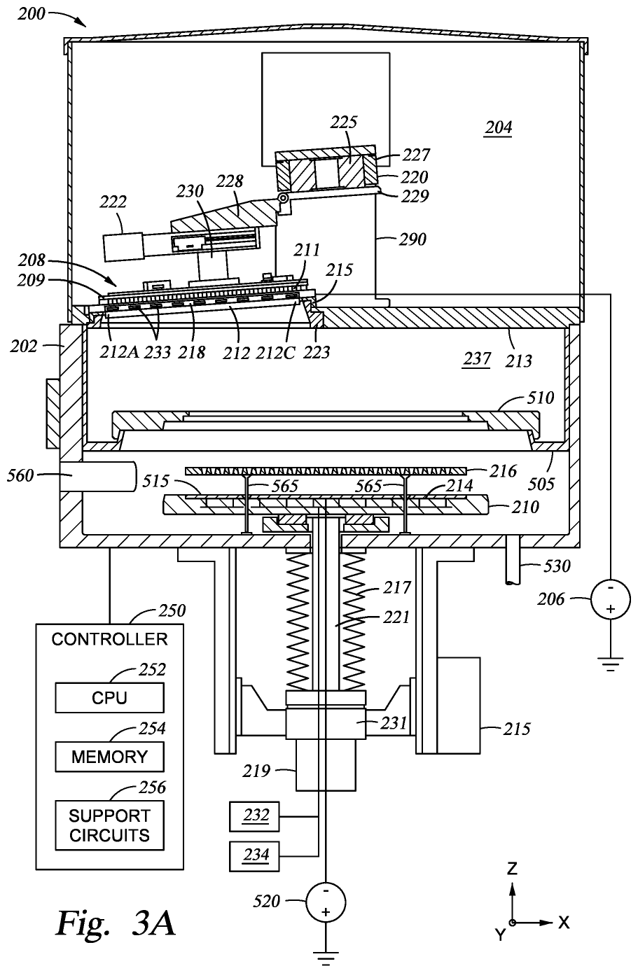

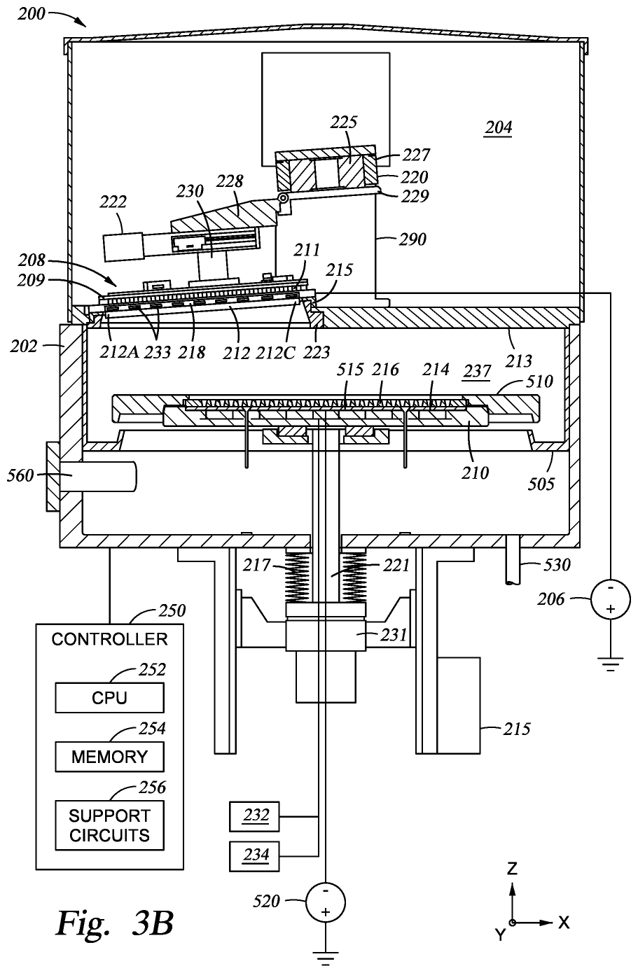

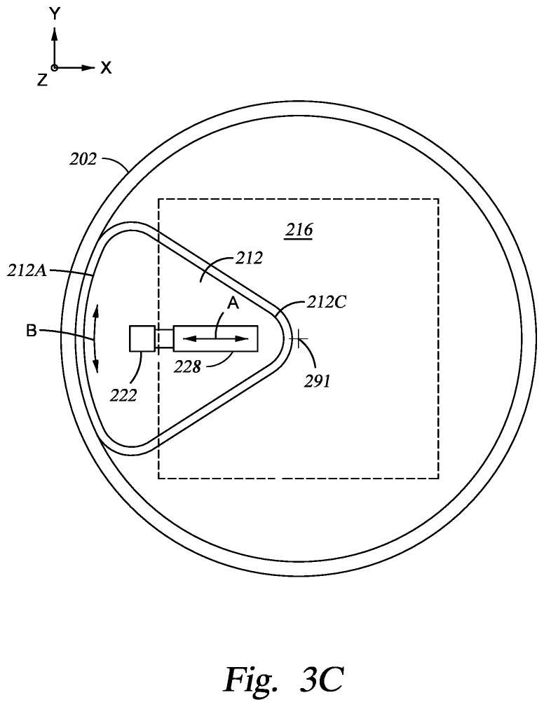

FIG. 3A is a side cross-sectional view of a PVD chamber 200 that may be used in the substrate processing system 100 of FIG. 2, according to certain embodiments. As will be described herein, the chamber of FIGS. 3A, 3B includes a target 212 in an upper portion of the chamber as well as a sacrificial plate 515, also constructed of target material, in a lower portion of the chamber whereby the thickness uniformity of material deposited on to surfaces of a substrate, by sputtering material from the target 212 and the sacrificial plate 515, can be controlled.” For example, the PVD chamber 200 may represent either one of the first or second deposition chambers 110-116 shown in FIG. 2. Alternatively, the PVD chamber 200 may represent an additional deposition chamber.

The PVD chamber 200 generally includes a chamber body 202, a lid assembly 204 coupled to the chamber body 202, a magnetron 208 coupled to the lid assembly 204, a substrate support assembly that includes a pedestal 210 and sacrificial plate 515 that are disposed within the chamber body 202, and a target 212 disposed between the magnetron 208 and the pedestal 210. During processing, the interior of the PVD chamber 200, or processing region 237, is maintained at a vacuum pressure. The processing region 237 is generally defined by the chamber body 202 and the lid assembly 204, such that the processing region 237 is primarily disposed between the target 212 and the substrate supporting surface of the pedestal 210.

A power source 206 is electrically connected to the target 212 to apply a negatively biased voltage to the target 212. In certain embodiments, the power source 206 is either a straight DC mode source or a pulsed DC mode source. However, other types of power sources are also contemplated, such as radio frequency (RF) sources.

The target 212 includes a target material 212M and a backing plate 218, and is part of the lid assembly 204. A front surface of the target 212 includes the target material 212M that defines a portion of the processing region 237. The backing plate 218 is disposed between the magnetron 208 and target material 212M. Typically, the backing plate 218 is an integral part of the target 212 and thus for simplicity of discussion the pair may be referred to collectively as the “target.” The backing plate 218 is electrically insulated from the support plate 213 of the lid assembly 204 by use of an electrical insulator 215 to prevent an electrical short being created between the backing plate 218 and the support plate 213 of the grounded lid assembly 204. As shown in FIG. 3A, the backing plate 218 has a plurality of cooling channels 233 configured to receive a coolant (e.g., DI water) therethrough to cool or control the temperature of the target 212. In certain embodiments, the backing plate 218 may have one or more cooling channels. In some examples, the plurality of cooling channels 233 may be interconnected and/or form a serpentine path through the body of the backing plate 218. A shield 223 is coupled to the support plate 213. The shield 223 prevents material sputtered from the target 212 from depositing a film on the support plate 213. In some embodiments, the magnetron 208 and target 212, which includes the target material and backing plate 218, each have a triangular or delta shape, such that a lateral edge of the target 212 includes three corners (e.g., three rounded corners shown in FIG. 3C). As illustrated in FIG. 3C, the target 212 is oriented such that a tip of a corner of the triangular or delta shaped target is at or adjacent to the center axis 291. When viewed in a planar orientation view, as shown in FIG. 3C, the surface area of the target 212 is less than the surface area of the substrate 216. In some embodiments, a surface area of the upper surface of the pedestal is greater than a surface area of the front surface of the target 212. In some embodiments, the ratio of the surface areas of the front surface of the target 212 to the deposition surface of the substrate 216 (e.g., upper surface of the substrate) is between about 0.1 and about 0.4.

As shown in FIG. 3A, the magnetron 208 is disposed over a portion of the target 212, and in a region of the lid assembly 204 that is maintained at atmospheric pressure. The magnetron 208 includes a magnet plate 209 (or yoke) and a plurality of permanent magnets 211 attached to the shunt plate. The magnet plate 209 has a triangular or delta shape with three corners (FIG. 3C). The magnets 211 are arranged in one or more closed loops. Each of the one or more closed loops will include magnets that are positioned and oriented relative to their pole (i.e., north (N) and south (S) poles) so that a magnetic field spans from one loop to the next or between different portions of a loop. The sizes, shapes, magnetic field strength and distribution of the individual magnets 211 are generally selected to create a desirable erosion pattern across the surface of the target 212 when used in combination with oscillation of the magnetron 208 as described below. In certain embodiments, the magnetron 208 may include a plurality of electromagnets in place of the permanent magnets 211.

The pedestal 210 has an upper surface 214 that would typically support a substrate during processing. However, in one embodiment of the invention a sacrificial plate 515 is disposed in a recess or pocket formed in the upper surface 214 of the pedestal in a manner whereby the substrate 216 will be substantially supported by the sacrificial plate 515 rather than the upper surface 214. In one embodiment, an RF bias source 520 is electrically coupled to the sacrificial plate 515 of the pedestal 210 to allow the plate 515 to be biased during the sputtering process. Biasing the sacrificial plate 515 not only facilitates the sputtering of the material from which the sacrificial plate 515 is formed, but also the material disposed on the surfaces of the TVs, such as the material deposited on the surface of the TVs from the target 212 and prior deposited material formed thereon from the sputtering of the sacrificial plate 515. The process of biasing the sacrificial plate 515 will also improve the density of a deposited layer, adhesion of the deposited layer, and profile of the deposited layer in the features formed on the substrate surface. In some embodiments, the bias applied to the sacrificial plate 515 includes a radio frequency (RF) bias that is provided at a desired power level and frequency, such as an RF frequency between 100 kHz to 100 MHz, or between 1 MHz and 60 MHz, such as 13.56 MHz. Additionally, a secondary source of processing gas 234 is provided to ensure a sufficient amount of gas is present in an area between an upper surface of the plate 515 and a bottom surface of the substrate 216 as will be described herein. In the embodiment of FIG. 3A, the substrate is shown in a loading positon having been introduced into the chamber by a robot (not shown) via a gate 560. In FIG. 3A, the substrate 216 is held at an upper end of a pair of pins 565 where it was placed by the robot.

FIG. 3B is a side cross-sectional view of the PVD chamber of FIG. 3A, shown with the substrate 216 in a processing position. Comparing the two Figures, the pedestal 210 in FIG. 3B has been raised in a manner whereby the substrate is supported by the sacrificial plate 515 at a lower side. A clamp 224 is used to hold the substrate 216 on the surface of the sacrificial plate 515. As the pedestal moves upwards, the clamp 224 is lifted from a ring 505 where it is supported during the loading portion of the process. In certain embodiments, the clamp 224 operates mechanically. For example, the weight of the clamp 224 may hold the substrate 216 in place.

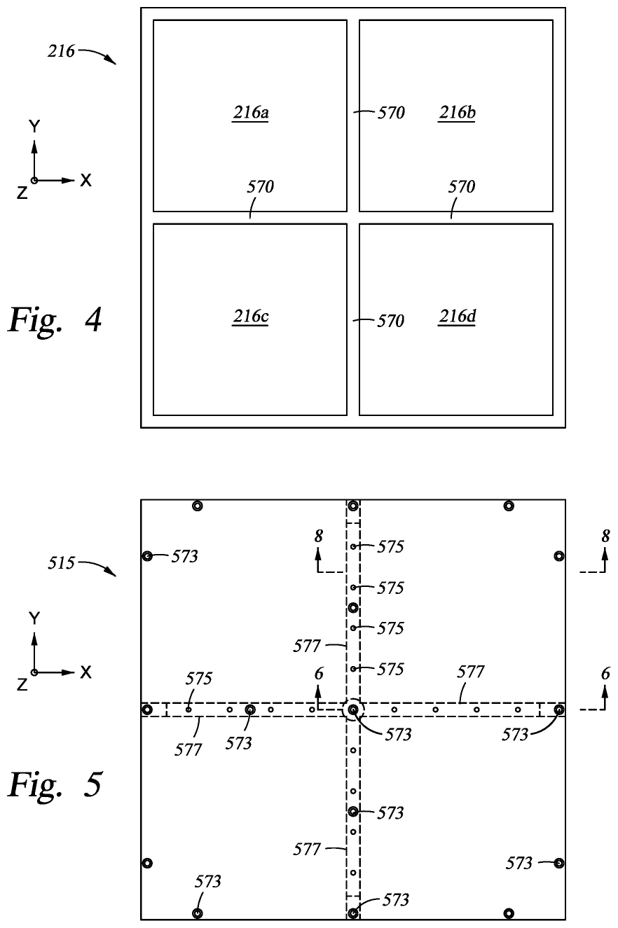

FIG. 4 is a top view of a substrate 500, which in one example, includes four segments 216a-d that each include an array of TVs formed therein to facilitate further processing of each portion. Segment dividers 570 surround each segment dividing them into discrete portions to facilitate separation at a later stage of processing. In one embodiment, the dividers are formed of non-target material and may have a reduced thickness to facilitate separation. To clarify the illustration, the segments 216a-d are shown without features, like one or more types of vias 500a-500c for example. In this example, the substrate 216 is a panel that includes four packaging substrates or interposer substrates that are positioned in the segments 216a-d. In certain embodiments, the substrate has external sides that are about 500 mm or greater in size, such as 510 mm by 515 mm or 600 mm by 600 mm. However, apparatus and methods of the present disclosure may be implemented with many different types and sizes of substrates.

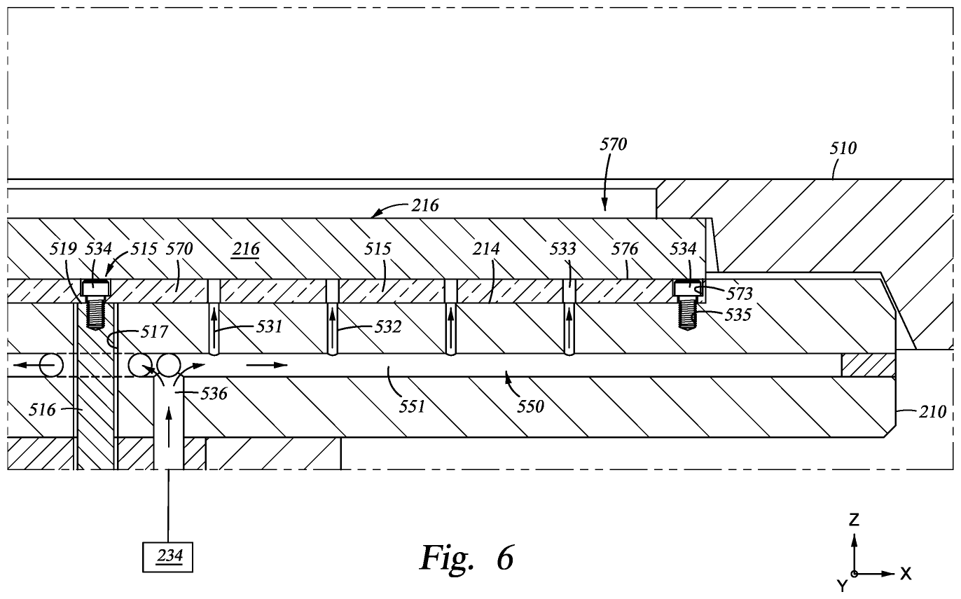

FIG. 5 is a top view of a sacrificial plate 515 that is constructed and arranged to sit between an upper surface of the pedestal 210 and a lower surface of the substrate 216 and provide an additional source of target material when the sacrificial plate 515 is biased during the sputtering process, especially when the substrate being processed includes TVs. As shown in FIGS. 6, 8 and 9, the substrate 216 is disposed on the upper surface of the sacrificial plate 515. The sacrificial plate 515 is provided with a plurality of gas apertures 575 and fastener features. In one embodiment, the fastening features include mounting holes, such as countersunk holes 573, that are used to affix the plate to the upper portion of the pedestal 210. In one embodiment, the countersunk holes 573, when used in conjunction with a threaded fastener 534, are used to align and affix the sacrificial plate 515 to the upper surface of the pedestal 210. In one embodiment, the apertures 575 and countersunk holes 573 are aligned and positioned to coincide with the segment dividers 570 of the substrate to avoid interference with or overlap with the substrate segments 216a-d. In one embodiment, the apertures 575 and countersunk holes 573 are aligned and positioned within one or more plate divider regions 577 of the sacrificial plate 515, which are aligned and positioned to coincide with the segment divider 570 regions of the substrate 216. The result is a predetermined number of gas apertures and a predetermined number of mounting holes disposed in the plate along a Y-axis of the plate and a predetermined number of each disposed along an X-axis of the plate. In one embodiment, the plate divider regions 577 divide the plate into two or more discrete sections. In one example, as shown in FIG. 5, four plate divider regions 577 each extend laterally through a center of the sacrificial plate 515, and thus the result is the sacrificial plate is divided into four quadrants 216a-d. While not intending to limit the scope of disclosure provided herein, in some embodiments, the plate divider regions 577 are between 1 mm and 20 mm wide, such as between 5 mm and 10 mm wide, and include at least the plurality of gas apertures 575.

In some embodiments, the upper surface 576 (FIG. 6) of the sacrificial plate 515 is substantially the same size (i.e., same X and Y dimensions) as the outer lateral edge dimensions of the substrate 216. In some other embodiments, the edges of the upper surface 576 of the sacrificial plate 515 is sized so that the lateral edges of the sacrificial plate 515 are positioned within the segment divider 570 regions found at the edge of a substrate 216 when a substrate is disposed on the sacrificial plate 515. In one non-limiting example, sacrificial plate 515 is smaller than the lateral dimensions of the substrate 216, such that the extent of the lateral edges of the sacrificial plate 515 are configured to be smaller by about 5 mm or less from each of the edge(s) of a substrate 216, or smaller by about 3 mm or less from each of the edge(s) of the substrate 216. In an alternate non-limiting example, the sacrificial plate 515 is larger than the lateral dimensions of the substrate 216, such that the extent of the lateral edges of the sacrificial plate 515 are configured to be larger by about 5 mm or less from each of the edge(s) of a substrate 216, or larger by about 3 mm or less from each of the edge(s) of the substrate 216. In the case where the sacrificial electrode 515 is larger than the substrate 216, a shielding structure (e.g., sheet metal piece) may be disposed between the surfaces of the sacrificial plate 515 and the substrate 216.

Preferably, the sacrificial plate 515 is formed of a material that is the same or similar to the target material from which the face of the target 212 is formed and can be formed from a material that is configured to form a desired film composition on the surface of the substrate 216. In one example, the sacrificial plate 515 material may include a pure material or alloy containing elements selected from the group of copper (Cu), molybdenum (Mo), nickel (Ni), titanium (Ti), tantalum (Ta), aluminum (Al), cobalt (Co), gold (Au), silver (Ag), manganese (Mn), and silicon (Si). In some embodiments, the materials from which the sacrificial plate is formed comprises a material that has a purity that is at least 99.9% (3N) pure, or at least 99.99% (4N) pure, or at least 99.999% (5N) pure, or at least 99.9999% (6N) pure, which can be determined by GDMS. In some embodiments, the material of the sacrificial plate is a polycrystalline material that has a desired maximum grain size, such as a maximum grain size that is less than 80 micrometers (μm), such as less 50 μm, or even less than 25 μm.

Considering FIG. 5 in more detail, the gas apertures 575 are disposed in a manner whereby, when the plate is installed between the pedestal 210 and the substrate 216, the apertures 575 align with the segment dividers 570 in a manner that maximizes their proximity to TVs formed in the substrate, while ensuring the target material of the sacrificial plate 515 is exposed to the lower side of the TVs 500 no matter where in the substrate segments 216a-d the vias might be formed. The purpose of the holes formed in the sacrificial plate, such as the countersunk holes 573, is to securely fasten the plate 515 to the upper surface of the pedestal 210, ensuring alignment between the gas apertures 575 and a source of gas (FIG. 6). In the embodiment shown, there is no center fastener hole in the divider region between the two right hand segments in order to ensure the plate 515, which is essentially square, is installed in a predetermined orientation on the pedestal 210.

The sacrificial plate 515 includes a connection member 517 that is configured to allow an electrical conductor 516 disposed within a shaft 221 of the pedestal 210 to be coupled thereto to allow the RF bias to be directly and safely applied to the sacrificial plate 515 during processing. In one embodiment, the electrical conductor 516 is a metal rod that includes a female threaded portion at one end that is configured to receive a threaded fastener 534 that extends through the connection member 517 (e.g., centrally positioned hole) formed in the sacrificial plate 515 to allow the electrical conductor 516 to be securely fastened to the lower surface of the sacrificial plate 515. The interface of a mating surface of the electrical conductor 516 and sacrificial plate 515 will have a desirable size (e.g., surface area) to assure that a reliable electrical contact can be formed at the desired RF bias levels achieved in the system. In some embodiments, the connection member 517 is centrally positioned within the sacrificial plate 515 to allow for the even distribution of the RF bias signal to the sacrificial plate 515 during processing. In another embodiment, the electrical conductor 516 may include a metal rod that includes a male threaded portion and shoulder portion at one end that is configured to be received by a mating threaded portion and shoulder receiving mounting surface of the connection member 517 formed in the sacrificial plate 515 so that electrical conductor is securely fastened to a connection portion 519 of the lower surface of the sacrificial plate 515. In one embodiment, the shoulder receiving mounting surface of the connection member 517 can include a flat region that is about the size of the outer dimension of the electrical conductor 516. In one configuration, the shoulder receiving mounting surface has a surface finish that is equal to an Ra of 32 pin or less. One skilled in the art will appreciate that configurations where the electrical conductor is not or cannot be securely fastened to the sacrificial plate 515 can lead to or cause arcing and damage to the process chamber and system when the electrical conductor is biased during processing.

FIG. 6 is a partial section view taken along a line 6-6 of FIG. 5 showing portions of the clamp 510, the ring 505, the substrate 216 and the sacrificial plate 515 as it would appear installed in the recessed area of the pedestal top 214. As shown, fasteners 534 have been installed in the mounting features 535 formed in the pedestal 210 to align and secure the sacrificial plate 515 to the top surface of the pedestal 210. In one example, the mounting features include a mechanical fastening elements, such as a threaded hole or threaded insert. Also included is a gas manifold assembly 550 integral to the pedestal 210 having a gas inlet 536, horizontal manifold 551 and gas outlets 532 leading to respective gas apertures 575 formed in the sacrificial plate 515. As shown by arrows 531, the gas flows within the manifold 551 to the gas apertures 575 and then to a space formed between the plate 515 and a lower surface of the substrate 216 in order to provide gas to a region between and also over the surface of the substrate 216 to facilitate the sputtering of the sacrificial plate 515 when it is biased by the RF bias source 520. Additionally, the presence of the gas in the space between the substrate 216 and the sacrificial plate 515 increases thermal conduction between the substrate 216 and the sacrificial plate 515 to control the temperature of the sacrificial plate 515 and substrate during processing. As discussed further below, in some embodiments, the pedestal 210 includes cooling channels (not shown) that are configured to control the temperature of the pedestal 210, sacrificial plate 515 and substrate 216 during processing. In FIGS. 5-6, the gas outlets and gas apertures are oversized for illustrative purposes. It will be understood that the structures, in particular the gas apertures 575, will be sized in a manner that creates a desired flow rate and velocity of gas appropriate for a particular sputtering operation. In some embodiments, the gas provided to the gas outlets and gas apertures includes a noble gas selected from a group of argon (Ar), krypton (Kr), neon (Ne) or xenon (Xe) and/or a reactive gas such as nitrogen (N₂) or oxygen (O₂) or helium (He) that is provided from the gas source 234.

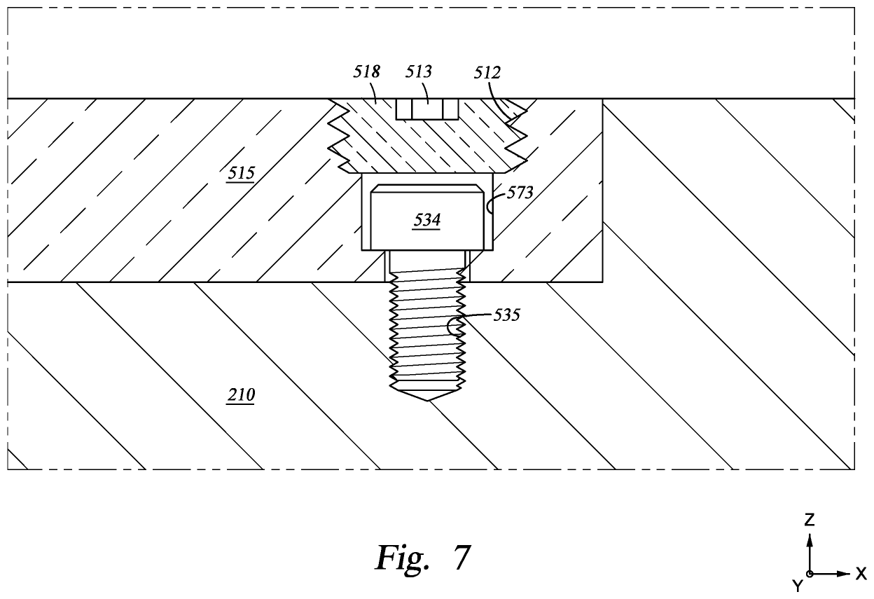

FIG. 7 is a partial section view of an embodiment that includes a protective cover 518 over a fastener 534 used to attach the sacrificial plate 515 to the pedestal 210. The cover 518 is typically formed from or heavily plated with the same material as the target and sacrificial plate 515. The purpose of the cover 518 is to prevent the material of the fastener, which is typically silver plated stainless steel, from being sputtered during a pasting process resulting in contamination. Because a plasma generated in a processing operation, due to a bias applied to the sacrificial plate 515, bombards any exposed surface (including the surface of fasteners), protecting fasteners 534 can be important for use in processes that do not include a substrate installed on the plate 210. It is envisioned that each fastener associated with the sacrificial plate can be protected in this manner. As shown, the fastener 534 is recessed into the plate, which may be increased in thickness. An enlarged diameter threaded feature 512 is formed in the plate to receive an externally threaded cover 518, which is equipped with an internally-formed hex head feature 513. In the example shown, there is a threaded relationship between the cover 518 and the plate 515, but the cover 518 could just as easily be press-fit into engagement with an upper portion of the mounting holes, such as the uppermost portion of the countersunk holes 573.

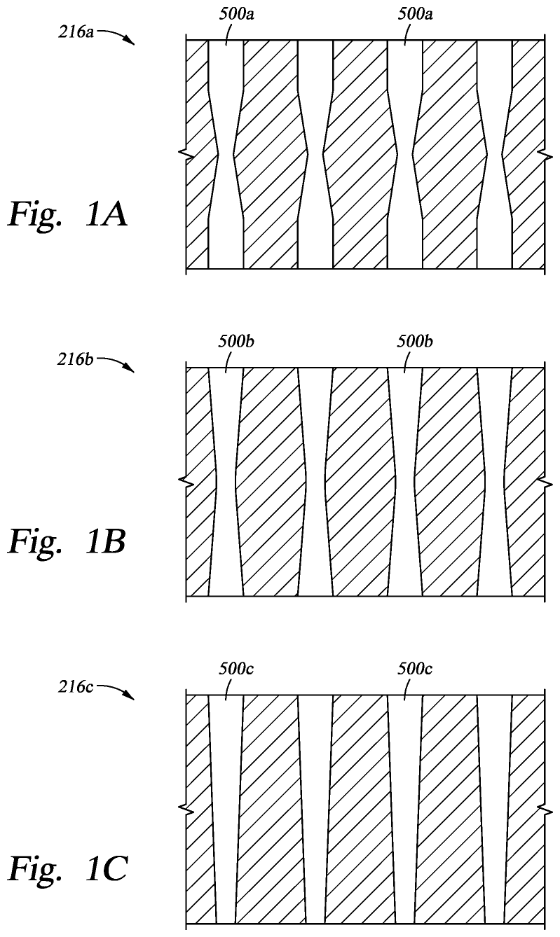

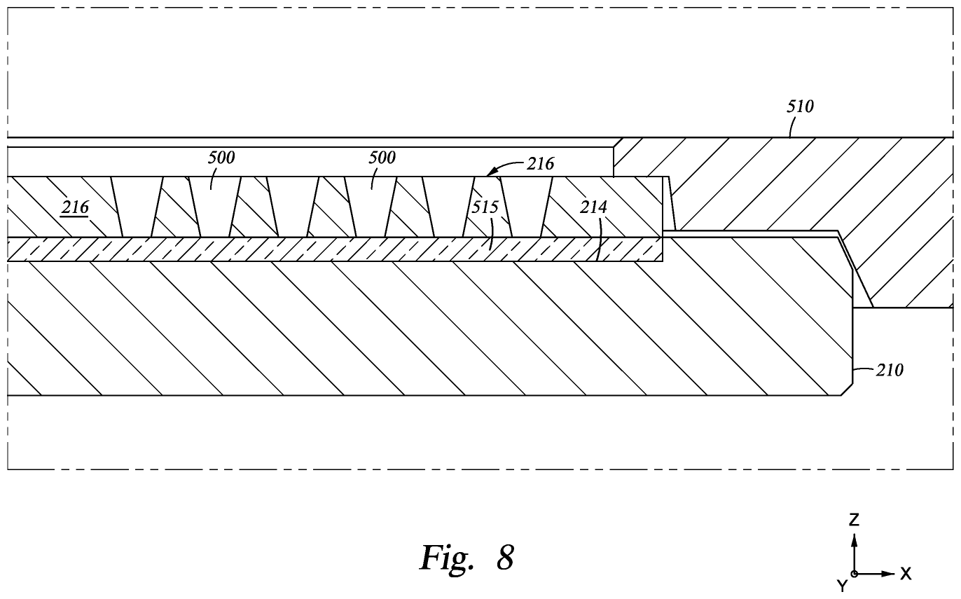

FIG. 8 is a pre-processing partial section view taken along a line 8-8 of FIG. 5 and illustrating the TVs formed in the substrate. The vias are shown with a cup-shaped interior but could have any interior design including those shown in FIG. 1. In FIG. 8, it can be appreciated that the lower opening of each TV is positioned over or in contact with the upper surface of the sacrificial plate 515. It will be appreciated however, that gas flowing through the adjacent gas apertures 575 (FIG. 6) will migrate in the space between the lower surface of the substrate 216 and the upper surface of the plate 515 to the TVs 500, providing processing gas to facilitate the deposition of the sputtered material provided from the surface of the sacrificial plate 515 onto the sides of the TVs.

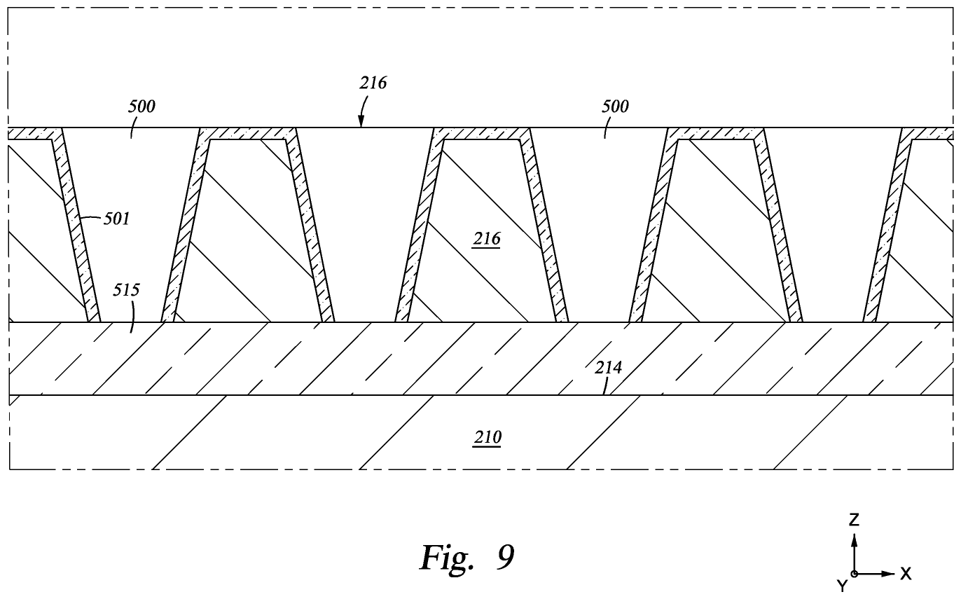

FIG. 9 is a partial section view illustrating the TVs shown in FIG. 8 after processing. As shown, the upper surface of each via has been coated with sputtered material 501 that was provided from the sputtering of the target material 212M and from the sputtering of the material of the sacrificial plate 515. Importantly, the sides of each via include a deposited layer that is substantially uniform, due to the sputtered target material provided from the target 212 as well as the material sputtered from sacrificial plate 515 below the substrate 216. In some embodiments, the gas pressure in the processing region 237 by a chamber gas source 539, power provided to the target 212 by the power source 206 and bias applied to the sacrificial plate 515 by the RF bias source 520 is controlled by the system controller 250 so that deposited film layer (i.e., sputtered material 501) disposed over the surface of the substrate 216 and surface of the vias is continuous and substantially uniform after processing.

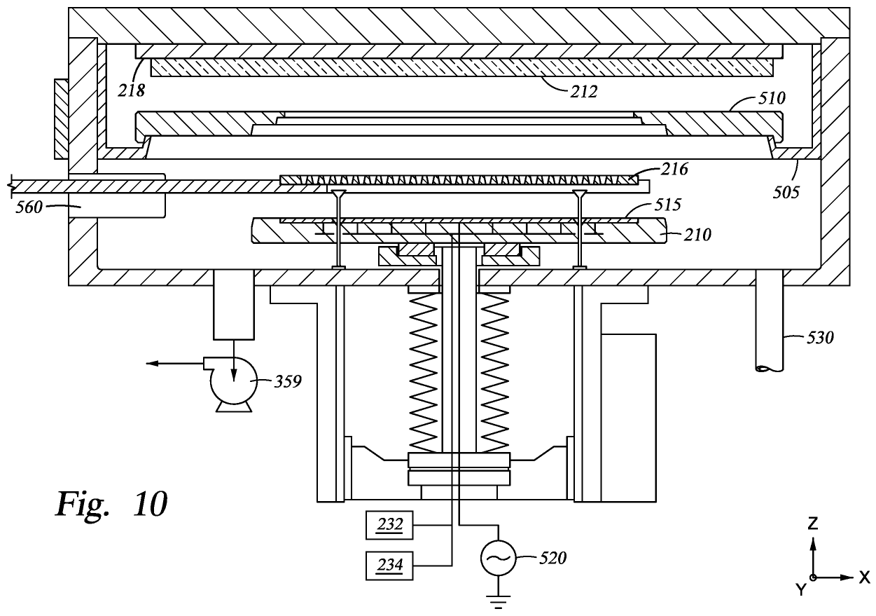

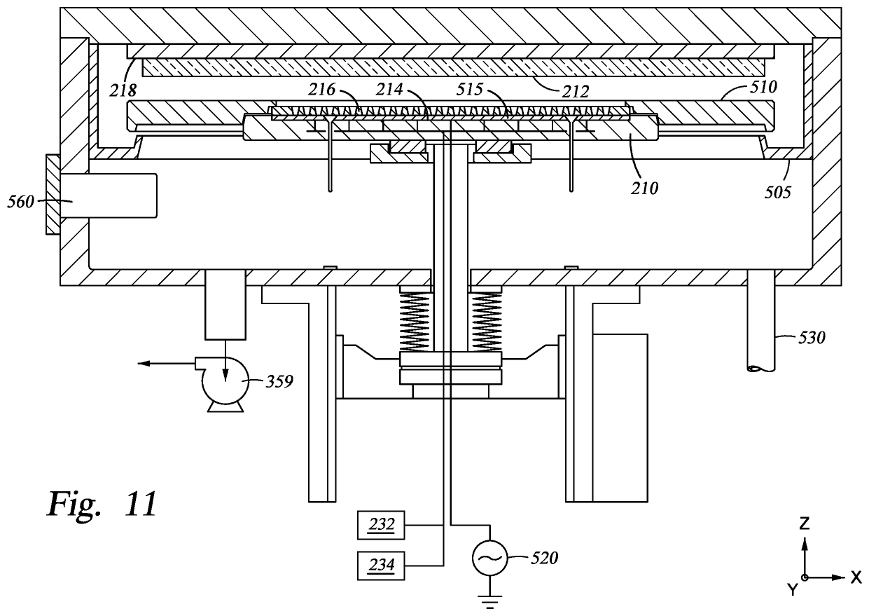

FIG. 10 is a section view of another embodiment of a PVD chamber including aspects of the invention and showing a substrate in a loaded position. A more simplified version of a PVD chamber, it includes a primary source of a process gas that is provided from the chamber gas source 539, a substrate 216 having a plurality of TVs, a sacrificial plate 515 disposed in a recessed top of a pedestal 210 and a biasing means (e.g., RF power source 520) for the sacrificial plate 515 in addition to a biasing means (e.g., power source 206 (FIG. 3A)) for the target 212 disposed at an upper end of the chamber. Like the embodiment shown and described in prior Figures, the sacrificial plate 515 includes gas apertures 575 that are constructed and arranged to align with gas outlets in the pedestal 210 leading from a manifold 551 and a source of gas 234. Like the previous embodiments, the sacrificial plate 515 is affixed to the receded top of the pedestal 210 with fasteners. FIG. 11 is a section view of the PVD chamber of FIG. 10, with the substrate in the processing position.

In these examples, the backside of the plate 515 is in contact with the recessed, upper surface 214 of the pedestal 210. In some examples, the entire backside of the substrate 216 may be in electrical and thermal contact with the upper surface 214 of the sacrificial plate. The temperature of the plate 515 and substrate 216 may be controlled using a temperature control system 232. In certain embodiments, the temperature control system 232 has an external cooling source that supplies coolant to channels (not shown) formed in a portion of the pedestal 210. In some embodiments, the external cooling source is configured to deliver a cryogenically cooled fluid (e.g., Galden®) to heat exchanging elements (e.g., coolant flow paths) within a sacrificial plate 515 and/or supporting portion of the pedestal 210 that is adjacent to the sacrificial plate 515, in order to control the temperature of the plate and or the substrate to a temperature that is less than 20° C., such as less than 0° C., such as about −20° C. or less. In some examples, the cooling source may be replaced or augmented with a heating source to increase the workpiece temperature independent of the heat generated during the sputtering process. Controlling the temperature of the substrate 216 is important during the sputtering process to obtain a predictable and reliable thin film that has desirable film properties.

A pedestal shaft 221 is coupled to an underside of the pedestal 210. A rotary union 219 is coupled to a lower end of the pedestal shaft 221 to provide rotary fluid coupling with the temperature control system 232 and rotary electrical coupling with the RF bias source 520. In certain embodiments, a copper tube is disposed through the pedestal shaft 221 to couple both fluids and electricity to sacrificial plate 515 within the pedestal 210. The rotary union 219 includes a magnetic liquid rotary sealing mechanism (also referred to as a “Ferrofluidic® seal”) for vacuum rotary feedthrough.

In certain embodiments, the pedestal 210 is rotatable about an axis perpendicular to at least a portion of the upper surface 214 of the pedestal 210. In this example, the pedestal 210 is rotatable about a vertical axis, which corresponds to the z-axis. In certain embodiments, rotation of the pedestal 210 is continuous without indexing. In other words, a motor driving rotation of the pedestal 210 does not have programmed stops for rotating the substrate 210 to certain fixed rotational positions. Instead, the pedestal 210 is rotated continuously in relation to the target 212 to improve film uniformity. In certain embodiments, the motor 231 is an electric servo motor. The motor 231 may be raised and lowered by a separate motor 215. The motor 215 may be an electrically powered linear actuator. A bellows 217 surrounds the pedestal shaft and forms a seal between the chamber body 202 and the motor 231 during raising and lowering of the pedestal 210.

An underside surface of the target 212, which is defined by a surface of a target material, faces towards the upper surface 214 of the pedestal 210 and towards a front side of the substrate 216. The underside surface of the target 212 faces away from the backing plate 218, which faces towards the atmospheric region or external region of the PVD chamber. In certain embodiments, the target materials of the target 212 are formed from a material for sputtering a corresponding film composition on the substrate 216. In one example, the target materials may include a pure material or alloy containing elements selected from the group of copper (Cu), molybdenum (Mo), nickel (Ni), titanium (Ti), tantalum (Ta), aluminum (AI), cobalt (Co), gold (Au), silver (Ag), manganese (Mn), and silicon (Si). In some embodiments, the target materials comprises a material that has a purity that is at least 99.9% (3N) pure, or at least 99.99% (4N) pure, or at least 99.999% (5N) pure, or at least 99.9999% (6N) pure, which can be determined by GDMS. In some embodiments, the target material is a polycrystalline material that has a desired maximum grain size, such as a grain size that is less than 80 μm, or less than 50 μm, or even less than 25 μm.

The materials deposited on a substrate 216 by the methods described herein may include pure metals, doped metals, metal alloys, metal nitrides, metal oxides, metal carbides containing these elements, as well as silicon containing oxides, nitrides or carbides.

In this example, the pedestal 210 is substantially horizontal, or parallel to the x-y plane, whereas the target 212 is non-horizontal, or tilted in relation to the x-y plane. However, other non-horizontal orientations of the pedestal 210 are also contemplated.

In the illustrated embodiments, a hinge 228 is used to couple a support body 230 of the magnetron 208 to the first actuator 220. The hinge 228 enables the magnetron 208 to be lifted and rotated out of the way of the backing plate 218. This provides easy access to the underside of the magnetron 208 and the topside of the backing plate 218 for performing maintenance, such as replacing the target 212.

A system controller 250, such as a programmable computer, is coupled to the PVD chamber 200 for controlling the PVD chamber 200 or components thereof. For example, the system controller 250 may control the operation of the PVD chamber 200 using direct control of the power source 206, the magnetron 208, the pedestal 210, cooling of the backing plate 218, the first actuator 220, the second actuator 222, the temperature control system 232, and/or the RF bias source 234, or using indirect control of other controllers associated therewith. In operation, the system controller 250 enables data acquisition and feedback from the respective components to coordinate processing in the PVD chamber 200.

The system controller 250 includes a programmable central processing unit (CPU) 252, which is operable with a memory 254 (e.g., non-volatile memory) and support circuits 256. The support circuits 256 (e.g., cache, clock circuits, input/output subsystems, power supplies, etc., and combinations thereof) are conventionally coupled to the CPU 252 and coupled to the various components of the PVD chamber 200.

In some embodiments, the CPU 252 is one of any form of general purpose computer processor used in an industrial setting, such as a programmable logic controller (PLC), for controlling various monitoring system component and sub-processors. The memory 254, coupled to the CPU 252, is non-transitory and is typically one or more of readily available memory such as random access memory (RAM), read only memory (ROM), floppy disk drive, hard disk, or any other form of digital storage, local or remote.

Herein, the memory 254 is in the form of a computer-readable storage media containing instructions (e.g., non-volatile memory), that when executed by the CPU 252, facilitates the operation of the PVD chamber 200. The instructions in the memory 254 are in the form of a program product such as a program that implements the methods of the present disclosure (e.g., middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

In operation, the PVD chamber 200 is evacuated and back filled with argon gas. The power source 206 applies a negative bias voltage to the target 212 to generate an electric field inside the chamber body 202. At this time, power source applies a negative bias voltage to the sacrificial plate to generate an additional electric field inside the chamber body 202. The electric field acts to attract gas ions, which due to their collision with the exposed surface of the target 212, generates electrons that enable a high-density plasma to be generated and sustained near the underside of the target 212. The plasma is concentrated near the surface of target material 212M due to the magnetic field produced by the magnetron 208. The magnetic field forms a closed-loop annular path acting as an electron trap that reshapes the trajectories of the secondary electrons ejected from the target material into a cycloidal path, greatly increasing the probability of ionization of the sputtering gas within the confinement zone. The plasma confined near the underside of the target 212 contains argon atoms, positively charged argon ions, free electrons, and neutral atoms (i.e., unionized atoms) sputtered from the target material. The argon ions in the plasma strike the target surface and eject atoms of the target material, which are accelerated towards the substrate 216 to deposit a thin film on the substrate surface.

Inert gases, such as argon, are usually employed as the sputtering gas because they tend not to react with the target material or combine with any process gases and because they produce higher sputtering and deposition rates due to their relatively high molecular weight.

FIG. 3C is a top view illustrating an overlay of the target 212 and the substrate 216 in relation to the chamber body 202 of FIG. 3A, according to certain embodiments. In certain embodiments, the outer radial edge 212A of the target 212 extends a distance of about 1 inch to about 3 inches, such as about 1.5 inches beyond a corner of the substrate 216. In certain embodiments, the inner radial edge 212C of the target 212 is spaced a distance of about 0.25 inches to about 0.75 inches, such as about 0.5 inches from the center axis 291 of the support post 290, which may be coincident with a radial center of the chamber body 202.

### Exemplary Substrate Processing System

As can be appreciated from FIG. 3A, the PVD chamber includes a target disposed on a backing plate in an upper portion of the chamber. A biasing source is provided to the target and a gas inlet provides process gas to the chamber. A pedestal at the lower end of the chamber supports a sacrificial plate 515 that, in one embodiment is made of the same material as the target 212. Mounted on the plate is a substrate typically having one or more TVs 500 formed therein. In one embodiment, the plate is provided with its own an RF bias source 520 biasing source as well as an additional source of process gas 234. A high vacuum pump is provided to create a vacuum within the chamber through an exhaust port 530. In the examples described herein, process gas, in one example Argon, interacts with the target at the top of the chamber and the target material is sputtered downward to form a film of material on the substrate as well as the walls of the TVs. In addition to the target, the sacrificial plate 515 is also acting as a second target with target material sputtered upwards in order to provide a second source of material to coat the walls of the vias 500. In one embodiment, the secondary source of process gas is provided at the same time and rate as the primary source. In other embodiments, the timing is adjusted depending up desired results of the sputtering of TVs.

Inert gases, such as argon, are usually employed as the sputtering gas because they tend not to react with the target material or combine with any process gases and because they produce higher sputtering and deposition rates due to their relatively high molecular weight.

In addition to the embodiments described herein, the chamber arrangement with the sacrificial plate can be operated without a substrate in the chamber. In these instances, the additional upwardly directed sputtering from the plate can encapsulate previously deposited target material on portions of the chamber interior. As described above, fasteners associated with the sacrificial plate and the pedestal can be protected with the covers 518 shown in FIG. 7. An operation performed for encapsulation purposes can be performed as follows: A PVD chamber is provided having a pedestal disposed within a processing region of the chamber wherein the pedestal has an upper surface that is configured to support a sacrificial plate having an upper surface, and wherein the sacrificial plate is disposed on the upper surface of the pedestal. A bias to the plate to facilitate sputtering and a lid assembly is provided comprising a target of the same material as the sacrificial plate. Thereafter, a processing operation within the chamber causes sputtered material from the target and/or the plate to cover interior portions of the chamber.

While the foregoing is directed to embodiments of the present disclosure, other and further embodiments of the disclosure may be devised without departing from the basic scope thereof, and the scope thereof is determined by the claims that follow.

What is claimed is:

1. A processing chamber, comprising:
a pedestal having an upper surface configured to support a sacrificial plate which is disposed between the upper surface of the pedestal and a substrate during processing;
an electrical conductor configured to contact a connection member formed in the sacrificial plate, wherein the electrical conductor is further configured to receive an electrical bias provided from a bias source;
a plurality of gas outlets integrally formed in the pedestal for providing a processing gas to gas apertures formed in the sacrificial plate; and
a plurality of mounting features formed in the pedestal, wherein the mounting features are used to fasten the sacrificial plate to the upper surface of the pedestal in a manner whereby one or more of the gas apertures formed in the sacrificial plate are aligned with the gas outlets formed in the pedestal.

2. The processing chamber of claim 1, wherein the gas outlets formed in the pedestal are coupled to a manifold assembly that is configured to be coupled to a gas source.

3. The processing chamber of claim 1, further comprising an actuator that is configured to rotate the pedestal about a first axis that extends through the sacrificial plate and the substrate during processing.

4. The processing chamber of claim 1, wherein the bias source comprises an RF source.

5. The processing chamber of claim 1, further comprising:
a target that comprises a target material; and
a sacrificial plate that comprises the target material.

6. The processing chamber of claim 5, wherein the target material comprises a material that is at least 99.99% pure and has a grain size that is less than less than 80 micrometers.

7. The substrate support of claim 6, wherein the target material comprises copper (Cu), titanium (Ti), or aluminum (Al).

8. The processing chamber of claim 1, further comprising a sacrificial plate comprising a target material, wherein the target material comprises copper (Cu), molybdenum (Mo), nickel (Ni), titanium (Ti), tantalum (Ta), aluminum (Al), cobalt (Co), gold (Au), silver (Ag), manganese (Mn), and silicon (Si).

9. A processing chamber, comprising:
a pedestal disposed within a processing region of a physical vapor deposition (PVD) chamber, the pedestal having an upper surface that is configured to support a sacrificial plate, wherein the sacrificial plate is disposed between the upper surface of the pedestal and a substrate during a PVD process;
an electrical conductor disposed within the pedestal and configured to contact a connection member formed in the sacrificial plate;
a first motor coupled to the pedestal, the first motor configured to rotate the pedestal and the sacrificial plate about a first axis that is perpendicular to at least a portion of the upper surface of the pedestal during the PVD process;
a biasing source electrically coupled to the electrical conductor; and
a lid assembly comprising a target, wherein a surface of the target defines a portion of the processing region, and comprises a target material.

10. The processing chamber of claim 9, wherein:
a surface area of the upper surface of the pedestal is greater than a surface area of the surface of the target; and
the surface of the target is tilted at a first angle in relation to a plane of the upper surface of the pedestal.

11. The processing chamber of claim 9, further comprising:
a magnetron disposed over a portion of the target, and in a region of the lid assembly that is maintained at atmospheric pressure;
a first actuator configured to translate the magnetron over a surface of the target; and
a second actuator configured to translate the magnetron in a second direction over the surface of the target.

12. The processing chamber of claim 9, further comprising a sacrificial plate, wherein the pedestal includes a plurality of gas outlets integrally formed in the pedestal for providing a processing gas to gas apertures formed in the sacrificial plate.

13. The processing chamber of claim 9, wherein the biasing source is configured to provide an RF signal to the sacrificial plate during the PVD process.

14. The processing chamber of claim 11, further comprising a rotary union coupled to the pedestal, the rotary union configured to provide a fluid path and a channel for electrical cabling associated with the biasing source during rotation of the pedestal about the first axis.

15. The processing chamber of claim 9, wherein the upper surface of the pedestal is configured to receive a square or a rectangular sacrificial plate.

16. The processing chamber of claim 9, wherein an edge of the target comprises three corners, and one of the three corners is radially positioned closer to the first axis than the two other corners of the three corners.

17. The processing chamber of claim 9, further comprising a sacrificial plate, wherein the target and sacrificial plate comprise the same material.

18. The processing chamber of claim 9, further comprising a sacrificial plate, wherein the target and sacrificial plate comprise different materials.

19. A method of processing a substrate in a processing chamber, comprising:
disposing a substrate on an upper surface of a sacrificial plate disposed on a pedestal positioned within a processing region of a physical vapor deposition (PVD) chamber, the pedestal having an upper surface that is configured to support the sacrificial plate; and
performing a PVD process within the processing chamber, wherein performing the PVD process comprises:
biasing a target that comprises a target material, wherein the target defines at least a portion of the processing region; and
biasing the sacrificial plate to facilitate sputtering of the upper surface of the sacrificial plate, wherein the sacrificial plate comprises the target material, and biasing the sacrificial plate causes the target material to be sputtered from the upper surface of the sacrificial plate onto features formed in the substrate.

20. The method of claim 19, wherein performing the PVD process further comprises:
rotating, by use a first motor, the pedestal and the sacrificial plate about a first axis that is perpendicular to the upper surface of the pedestal and the upper surface of the sacrificial plate.
